(19) United States
(12) Patent Application Publication
(10) Pub. No.: US 2012/0039344 A1
(43) Pub. Date: Feb. 16, 2012

(54) GRAPHENE-BASED SATURABLE ABSORBER DEVICES AND METHODS

(76) Inventors: Loh Ping Kian, Singapore (SG); Oiaoliang Bao, Singapore (SG); Ding Yuan Tang, Singapore (SG); Han Zhang, Singapore (SG)

(21) Appl. No.: 13/263,738

(22) PCT Filed: Apr. 13, 2010
(86) PCT No.: PCT/SG2010/000148

§ 371 Date: Oct. 8, 2011

Related U.S. Application Data
(60) Provisional application No. 61/168,661, filed on Apr. 13, 2009.

(51) Int. Cl. H01S 3/30; B05D 5/06; B32B 37/02; B32B 37/12; B29C 35/08; C30B 23/02; C30B 25/02; H01S 3/08; B32B 37/14; B82Y 20/00; B82Y 40/00

(52) U.S. Cl. 372/6; 372/98; 427/162; 156/60; 156/150; 156/272.8; 264/400; 117/84; 977/842; 977/902

(57) ABSTRACT

A graphene-based saturable absorber device suitable for use in a ring-cavity fiber laser or a linear-cavity fiber laser is disclosed. The saturable absorber device includes an optical element and a graphene-based saturable absorber material supported by the optical element and comprising at least one of graphene, a graphene derivative and functionalized graphene. An examplary optical element is an optical fiber having an end facet that supports the saturable absorber material. Various forms of the graphene-based saturable absorber materials and methods of forming same are also disclosed.

### CLAIM OF PRIORITY

This Application claims priority from U.S. Provisional Patent Application Ser. No. 61/168,661, entitled “Optical element,” filed on Apr. 13, 2009.

### FIELD

The present invention relates to saturable absorbers for fiber lasers, and in particular relates to graphene-based saturable absorber devices and methods for use in fiber lasers for mode-locking, Q-switching, optical signal processing and the like.

### BACKGROUND ART

Fiber mode-locked lasers have replaced bulk solid state lasers in many research/industrial fields that need high-quality optical pulses. The advantages include simplicity of structure, outstanding pulse quality and efficient operation. The development of compact, diode-pumped, ultrafast fiber lasers as alternatives for bulk solid-state lasers is making rapid progress recently.

At present, short pulse generation has been particularly effective using passive mode-locking techniques. The dominant technology in passively mode-locked fiber lasers is based on semiconductor saturable absorber mirrors (SESAMs), which use III-V semiconductor multiple quantum wells grown on distributed Bragg reflectors (DBRs).

However, there are a number of drawbacks associated with SESAMs. SESAMs require complex and costly clean-room-based fabrication systems, such for Metal-Organic Chemical Vapor Deposition (MOCVD) or Molecular Beam Epitaxy (MBE). Also, an additional substrate removal process is needed in some cases. High-energy heavy-ion implantation is required to introduce defect sites in order to reduce the device recovery time (typically a few nanoseconds) to the picosecond regime required for short-pulse laser mode-locking applications.

Since a SESAM is a reflective device, its use is restricted to only certain types of linear cavity topologies. Other laser cavity topologies, such as the ring-cavity cavity design, which requires a transmission-mode device, which offers advantages such as doubling the repetition rate for a given cavity length, and which is less sensitive to reflection-induced instability with the use of optical isolators, is not possible unless an optical circulator is employed, which increases cavity loss and laser complexity. SESAMs also suffer from a low optical damage threshold.

Until recently, there has been no alternative saturable absorbing materials to compete with SESAMs for the passive mode-locking Of fiber lasers. Recently, the discovery of saturable absorption properties in single-wall carbon nanotubes (SWCNTs) in the near-infrared region with ultrafast saturation recovery times of ˜1 picosecond has produced a new type of solid saturable absorber quite different from SESAMs in structure and fabrication, and has, in fact, led to the demonstration of pico- or subpicosecond erbium-doped fiber (EDF) lasers. In these lasers, solid SWCNT saturable absorbers have been formed by direct deposition of SWCNT films onto flat glass substrates, mirror substrates, or end facets of optical fibers.

However, the non-uniform chiral properties of SWCNTs present inherent problems for precise control of the properties of the saturable absorber. The SWCNTs that are not in resonance cause insertion losses while operating at a particular wavelength. Thus, SWCNTs have poor wideband tunability. Furthermore, the presence of bundled and entangled SWCNTs, catalyst particles, and the formation of bubbles cause high nonsaturable losses in the cavity, despite the fact that the polymer host can circumvent some of these problems to some extent and afford ease of device integration.

### SUMMARY

An aspect of the invention is directed to a novel saturable absorber material consisting of graphene or its derivatives, and its assembly on an optical element, such as an optical fiber, to replace SESAMs and SWCNTs as saturable absorbers for short pulse generation.

The present invention overcomes the problems described above, namely better performance, cheaper fabrication and easier integration with the fabrication process compared to conventional methods involving SESAMS or SWCNTs.

Graphene is a material that is mechanically and chemically robust, exhibiting high conductivity and advantageous optical properties, such as interband optical transition and universal optical conductance. In terms of its use as saturable absorber, graphene materials also have lower non-saturable loss, higher conversion efficiency and wideband tunability.

The ultrafast recovery time of graphene also facilitates ultrashort pulse generation (picosecond to femtosecond pulses). The optical modulation depth can be tuned over a wide range by using single to multilayer graphene or doping/intercalating with other materials. The present invention uses graphene, graphene derivatives and graphite composites (eg. polymer-graphene, graphene gel) as saturable absorber materials for use in a fiber laser for mode-locking, Q-switching, optical pulse shaping, optical switching, optical signal processing and the like.

### BRIEF DESCRIPTION OF THE DRAWINGS

FIG. 1 is perspective, close-up end view of a saturable absorber device in the form of an optical fiber held within a ferrule, the fiber having an end facet that has assembled thereon a saturable absorber material comprising one atomic layer graphene;

FIG. 2 is perspective, close-up end view of a saturable absorber device in the form of an optical fiber held within a ferrule, the fiber having an end facet that has assembled thereon a saturable absorber material comprising several atomic layers of graphene to form a multilayer graphene film;

FIG. 3 is a perspective view of a saturable absorber device in the form of a fiber pigtail with a multilayer graphene film arranged on the fiber pigtail end;

FIG. 4 is an optical image of a fiber pigtail end having a multilayer graphene film arranged thereon and covering the ferrule pinhole;

FIG. 5 is perspective, close-up end view of a saturable absorber device in the form of an optical fiber having an end facet that has assembled thereon a saturable absorber material comprising one monolayer of small flakes of graphene;

FIG. 6 is perspective, close-up end view of a saturable absorber device in the form of an optical fiber held within a ferrule, the fiber having an end facet that has assembled thereon a saturable absorber material comprising graphene and polymer composites;

FIG. 7 is perspective, close-up end view of a saturable absorber device in the form of an optical fiber held within a ferrule, the fiber having an end facet that has assembled thereon a saturable absorber material comprising a hybrid film of graphene combined with other thin films materials;

FIG. 8 is a schematic diagram of an example fiber laser having a ring cavity that uses a graphene-based saturable absorber device; and

FIG. 9 is a schematic diagram of a fiber laser having a linear cavity that uses a graphene-based saturable absorber device.

### DETAILED DESCRIPTION

Aspects of the present invention are directed to the use of graphene, as well as its derivatives, such as graphene oxide or functionalized graphene, as a saturable absorbing material supported by an optical element (e.g., an optical fiber, a glass substrate, a mirror, etc.) to form a graphene-based saturable absorber device. The device is used, for example, in fiber lasers. The graphene-based saturable absorber device can exhibit an optical switching operation by a transmittance change accompanying saturable absorption by the graphene-based saturable absorber material. The graphene-based saturable absorber device can also be used for pulse shaping. The graphene can be incorporated as a graphene film or films, or as composites of graphene and polymer, or as composites of graphene and organic or inorganic materials. The graphene-based saturable absorber device can be used in fiber lasers for optical signal processing, mode locking, Q-switching, pulse-shaping and the like.

Generally speaking, a saturable absorber is an optical component with a certain optical loss, which is reduced at high light intensity. The main applications of a saturable absorber are in the mode locking and Q-switching of lasers, i.e., the generation of short pulses. However, saturable absorbers can also find applications generally in the processing of optical signals. An aspect of the present invention is the use of graphene, as well as its derivatives, as a saturable absorber material for a graphene-based saturable absorber device for use in fiber lasers for optical signal processing, mode locking, Q-switching, pulse-shaping and the like.

Graphene, a single atomic layer of sp²-hybridized carbon forming a honeycomb crystal lattice, has a linear energy spectrum near the intersection of the electron and hole cones in the band structure (the Dirac point). Since a 2+1 dimensional Dirac equation governs the dynamics of quasiparticles in graphene, many of its properties differ significantly from those of other materials. The optical conductance of monolayer graphene is defined solely by the fine structure constant, α=e²/c. The expected absorbance has been calculated and measured to be independent of frequency with a significant fraction (πα=2.293%) of incident infrared-to-visible light. In comparison, a 10-nm-thick GaAs layer absorbs about 1% of the light near the band gap. In principle, the photon interband absorption in zero-gap graphene could be easily saturated under strong excitation due to Pauli blocking, i.e., the photogenerated carriers cool down within subpicosecond to form a hot Fermi-Dirac distribution and the newly created electron-hole pairs block some of the originally possible optical transitions.

As the excitation is increased to high enough intensity, the photogenerated carriers have large concentration (much larger than the intrinsic electron and hole carrier densities of about 8×10¹⁰ cm⁻² in graphene at room temperature) and could cause the states near the edge of the conduction and valence bands to fill, blocking further absorption, thus it becomes transparent to light at photon energies just above the band edge. Band-filling occurs because no two electrons can fill the same state. Thus, saturable absorption or absorption bleaching is achieved due to this Pauli blocking process. In principle, graphene could be a perfect saturable absorber.

The intensity-dependent attenuation allows the high-intensity components of an optical pulse to pass through graphene thin films, while the lower intensity components of the pulse, such as the pulse wings, pedestals, or the background continuous wave (cw) radiation, does not.

When a saturable absorber in the form of a graphene film is placed in a lasing cavity, it will favour short pulse generation and suppress continuous-wave (cw) radiation, which can be used for mode locking. For the ultrashort pulse generation application, graphene has a fast recovery time at about 200 fs scale or less, which is required for stabilizing laser mode locking, while a slower recovery time at several ps scale could facilitate laser self-starting.

The present invention is not limited to assembled atomic-scale graphene nanosheets, but also includes its derivatives, for example functionalized graphene or graphene-polymer composites, supported by an optical element (e.g., on the end facet of an optical fiber) as saturable absorber for the mode locking of lasers. Advantageously, a graphene thin film with or without uniform layers may be assembled onto the end facet of an optical fiber as a saturable absorber. Advantageously, the assembly of small-size graphene flakes onto the end facet of an optical fiber to form a saturable absorber device is described. Advantageously a saturable absorber thin film may be comprised of at least one layer of graphene, graphene flakes or its functionalized derivatives onto the end facet of an optical fiber.

Furthermore, the intercalation of graphene or graphene functionalized derivatives with other thin films materials (e.g., polymers, organic dyes, inorganic materials) may be assembled on the end facet of an optical fiber to form a saturable absorber device for mode locking laser or relevant signal processing devices.

Graphene, as the term is used herein, is defined as single or multiple layers of graphene, as described, for example, in the publication by Novoselov, K. S. et. al. PNAS, Vol. 102, No. 30, 2005, and the publication by Novoselov, K. S. et. al. Science, Vol 306, 2004. Example graphene films considered herein comprise at least one layer of graphene, or one or more (e.g., a network or nanomesh of) graphene flakes. The graphene as considered in the present invention describes the material, and is not restricted by the methods use to prepare the material, which methods include mechanical exfoliation, epitaxial growth, chemical vapor deposition and chemical processed (solution processed) methods, as well as laser ablation and filtered cathodic arc methods.

Graphene is a single atomic layer of sp²-hybridized carbon forming a honeycomb crystal lattice. One atomic layer of graphene absorbs a significant fraction (2.293%) of incident light from infrared wavelengths to visible wavelengths. The photon interband absorption in zero-gap graphene could be easily saturated under strong excitation due to Pauli blocking. Therefore, graphene can be used as a saturable absorber material to form a wideband tunable saturable absorber device for photonics devices such as fiber lasers.

Other features and advantages of the invention are described in the Figures. One or more of the above-disclosed embodiments, in addition to certain alternatives, are provided in further detail below with reference to the attached Figures. The invention is not limited to any particular embodiment disclosed and is defined by the scope of the claims.

The term “graphene-based” is used herein and in the claims as shorthand to mean graphene, a graphene derivative, functionalized graphene, or a combination thereof.

### EXAMPLE 1

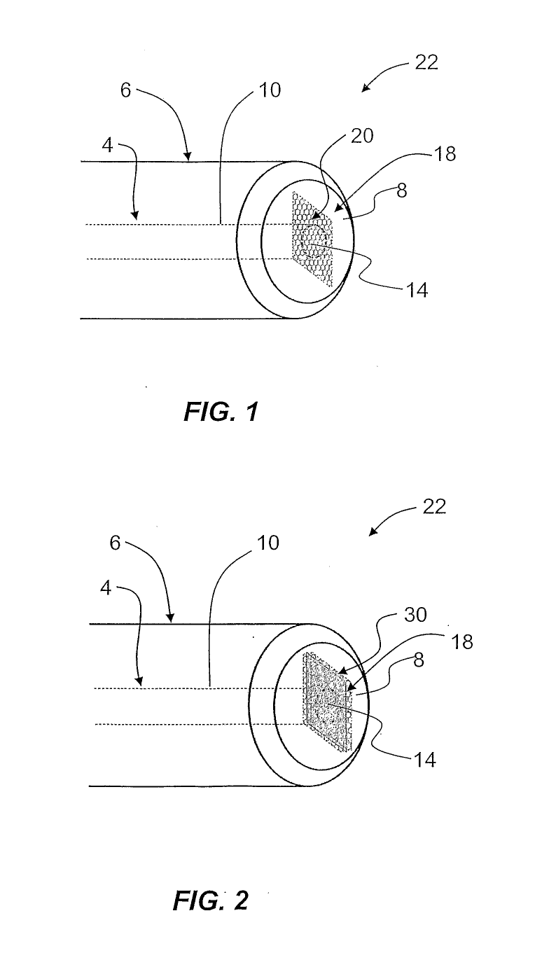

FIG. 1 is perspective view of an optical fiber 10 having an end facet 14 that has assembled thereon a graphene-based saturable absorber material 18 in the form of a monolayer graphene film 20 (i.e., one atomic layer of graphene, or “graphene monolayer”) to function as a saturable absorber device 22. The saturable absorber device 22 of FIG. 1 is suitable for use in mode locking and Q-switching fiber lasers, as described below. FIG. 1 shows optical fiber 10 held within an axial pinhole 4 of a ferrule 6 that has an endface 8. Ferrule 6 serves as a fiber holder.

A graphene monolayer 20 can be obtained using methods such as, for example, mechanically exfoliation, epitaxial growth, chemical vapor deposition and chemical processed (solution processed) methods, as well as laser ablation and filtered cathodic arc methods. After graphene monolayer 20 has been properly prepared on a substrate, the monolayer is removed as a graphene film and is transferred onto the end facet 14 of optical fiber 10.

In one example, graphene structures (e.g., graphene monolayer 20 and graphene multilayers, as discussed below) were produced by chemical vapor deposition (CVD) method. In one example process to grow graphene monolayer, a piece of copper (Cu) foil was loaded into the CVD chamber and a flow rate of H₂ at 10 sscm was maintained. The copper foil was heated up to about 1000° C. for the activation of the copper catalyst. Following, CH₄ was introduced into the chamber at 110 sscm for 30 minutes. CH₄ is catalytically decomposed on the Cu surface and the carbon atoms adsorbed to form monolayer graphene on the Cu surface upon cooling of the sample. The system was cooled to room temperature at a rate of approximately 10° C. Is under the protection of H₂ gas flow. The monolayer graphene film grown from this method is continuous with uniform thickness and is as big as the dimension of the copper foil.

In another experiment to grow graphene multilayers, a SiO₂/Si substrate with 300 nm Nickel (Ni) film was loaded into a CVD chamber. Then, the Ni catalyst was activated at 700° C. in 100 sccm H₂ gas flow. The samples were heated up to 900° C.˜1000° C. inside a quartz tube under the flow of Ar/CH₄/H₂ mixture flow (Ar:CH₄:H₂:=3:1:1) and reacted for 10 minutes. Finally, the system was allowed to rapidly cool down to room temperature at the rate of about 10° C./s under the protection of Ar gas flow. Then carbon atoms precipitated as a graphene layer on the Ni surface upon cooling of the sample since the solubility of carbon in Ni is temperature-dependent. The thickness of the graphene films can be controlled between monolayer to multilayer by the flow rate of the reactant and growth time. The graphene film produced using this method can be continuous over the dimension of the substrate.

To remove the graphene films from the substrate, an aqueous iron (III) chloride (FeCl₃) solution (approx. 1M) was used as an oxidizing etchant to remove the Cu/Ni layers. The redox process slowly etches the Cu/Ni layers effectively while the sample floats on the FeCl₃ solution surface. Before the graphene film was totally separated from the substrate, the sample was gently transferred into de-ionized (DI) water and it was kept there for at least ten hours. Then the graphene film was subsequently delaminated from Cu/Ni layers by dipping the samples into water using a floating off process to obtain a freestanding film. Before etching reaction, the dry Cu foil or Ni/SiO₂ substrate was cut into several sections so as to obtain graphene sheets with required size.

The transfer processes can be adjusted to suit the specific method and substrate used for preparing the graphene film.

### EXAMPLE 2

FIG. 2 is similar to FIG. 1 and is perspective view of optical fiber 10 with a graphene-based saturable absorber material 18 in the form of multilayer graphene film 30 (i.e., multiple atomic layers of graphene, or a “graphene multilayer”) assembled on fiber end facet 14 to function as a saturable absorber device 22. The saturable absorber device 22 of FIG. 2 is suitable for use in mode locking and Q-switching fiber lasers, as described below.

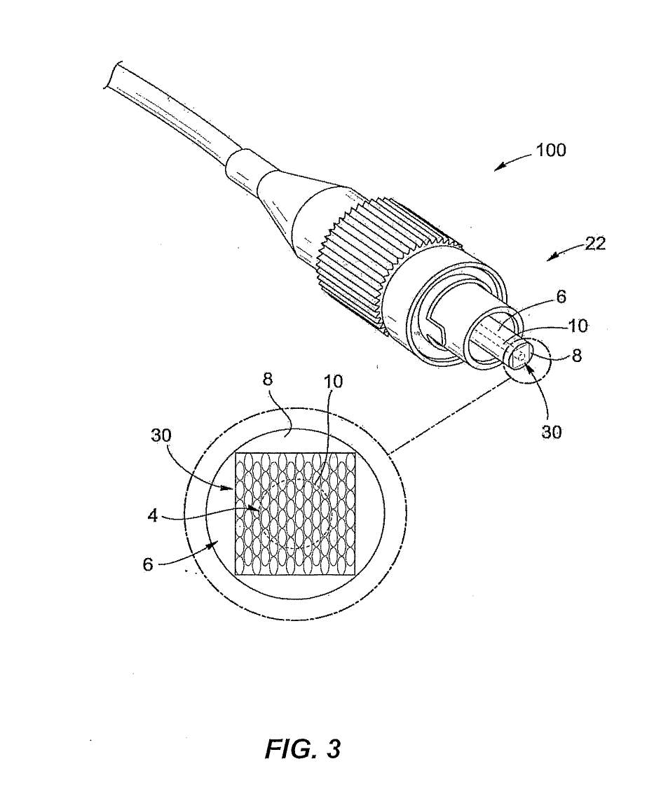

FIG. 3 is a photograph of a fiber pigtail 100 with ferrule 6 that holds optical fiber 10, with multilayer graphene film 30 on endface 8 covering pinhole 4 and fiber end facet 14. Fiber pigtail 100 is inserted into a fiber laser to generate mode locking or Q-switching pulses, as described below.

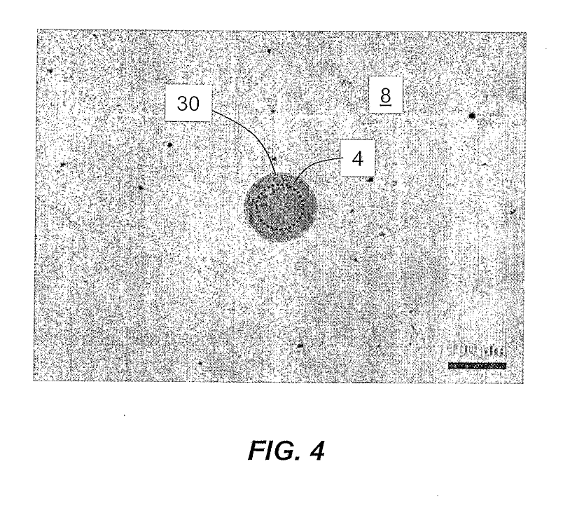

FIG. 4 is an enlarged optical image of the end face of fiber pigtail 100 showing a graphene-based saturable absorber material 18 in the form of multilayer graphene 30 on ferrule endface 8 covering pinhole 4 and fiber end facet 14. The as-prepared fiber pigtail 100, which can be considered as a saturable absorber device, is inserted into a fiber laser to generate mode locking or Q-switching pulses. The multilayer graphene 30 can be assembled using, for example, an electrostatic layer-by-layer method, transfer print or optical trapping methods.

The transfer processes differ according to the method and substrate used for preparing the graphene film. An example is to use a PDMS stamp to transfer print graphene film onto fiber end facet 14, which is suitable for a wide range of initial substrates where graphene or its derivatives is prepared. For the graphene film produced by epitaxial growth and chemical vapour deposition, the graphene film is detached from the original substrate by floating-off process, such as etching the substrate in acid or salt solution. Then the graphene film can be attached onto a target substrate by contacting them together due to strong van der Waals force.

For mechanically exfoliated graphene, the tape after initial peeling is attached directly onto fiber end facet 14 by careful aligning the graphene with the fiber pinhole 4.

Another example uses assemble technologies relying on electrostatic interaction, such as layer-by-layer to assemble graphene or its derivatives on the fiber end facet 14, which is suitable for solution processed graphene of graphene dispersed in solvents.

Yet another example uses optical trapping to attach graphene onto fiber end facet, in which the clean optical fiber which is connected with a laser source with tunable optical parameters is dipped into graphene solution.

### EXAMPLE 3

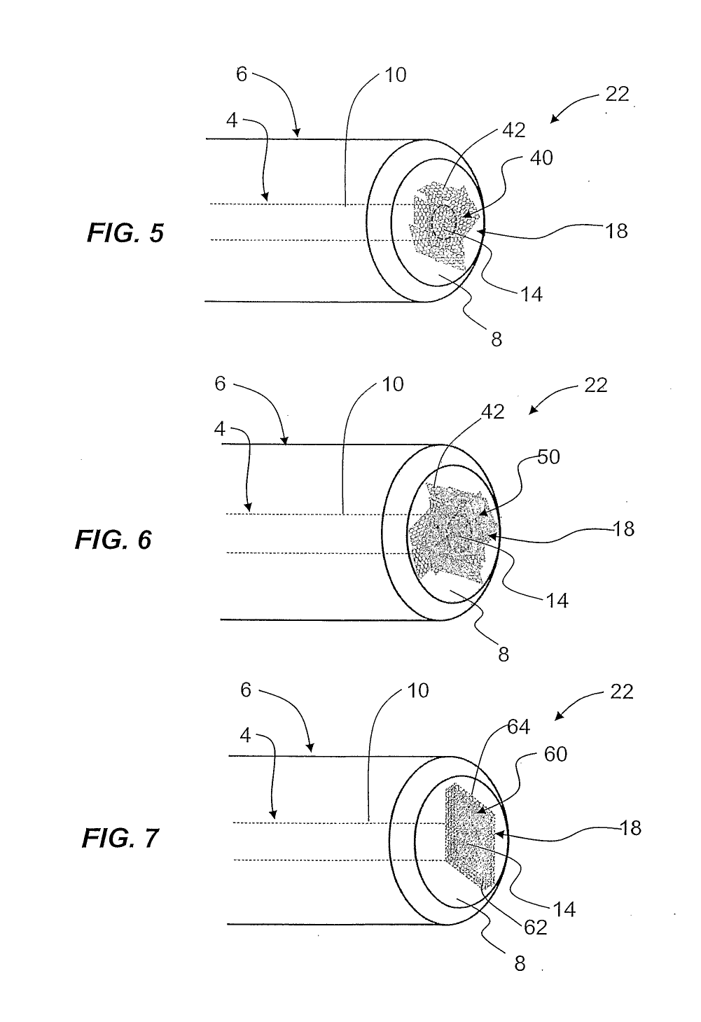

FIG. 5 is perspective view of optical fiber 10 similar to FIG. 1 and having a graphene-based saturable absorber material 18 in the form of graphene film 40. Graphene film 40 is formed form monolayer graphene flakes 42 assembled on fiber end facet 14, thereby forming saturable absorber device 22. The saturable absorber device 22 of FIG. 5 is suitable for use in mode locking and Q-switching fiber lasers, as described below.

In an example, monolayer graphene flakes 42 have a small size, e.g., less than 10 μm. In an example, graphene flakes 42 are assembled onto the end facet of fiber pigtail as a graphene film 40 that covers the pinhole 4, and the pigtail 100 is inserted into a fiber laser to generate mode locking or Q-switching pulses. The small size of graphene flakes 42 are obtained in one example by solution processing routes or by post-treatment of monolayer graphene on a substrate. The post-treatment method includes, but are not limited to, etching chemically (e.g., acid etching) or physically (e.g., electron bombing), or UV exposure. An example to transfer originally small-size graphene flakes 42 onto the fiber end facet 14 is to use assembly technologies, such as layer-by-layer, transfer print or optical trapping.

### EXAMPLE 4

FIG. 6 is perspective view of optical fiber 10 similar to FIG. 1 and having a graphene-based saturable absorber material 18 in the form of a graphene film 50 that comprises a multilayer of graphene flakes 42 assembled thereon to function as a saturable absorber device 22. The saturable absorber device of FIG. 6 is suitable for use in mode locking and Q-switching fiber lasers, as described below.

Graphene flakes 42 may have a small size (e.g., less than 10 μm). In an example, graphene flakes 42 are assembled on the fiber end facet 14 of the fiber pigtail 100 to cover the pinhole 4, and the fiber pigtail is inserted into a fiber laser to generate mode locking or Q-switching pulses. The multilayer graphene film 50 comprises a thin film of small-size multilayer graphene flakes 42, or alternatively comprises several layers of stacked thin films 40 in which each layer (film) comprises monolayer graphene flakes 42 with a small size (e.g., less than 10 μm).

Small-size graphene flakes 42 are obtained by solution-processing routes or by post-treatment of monolayer graphene on a substrate. The post-treatment methods include, but are not limited to, etching chemically (e.g., acid etching) or physically (e.g., electron bombing), or UV exposure. The small-size graphene flakes 42 can be transferred onto the fiber end facet using assembly technologies such as layer-by-layer, transfer print or optical trapping.

### EXAMPLE 5

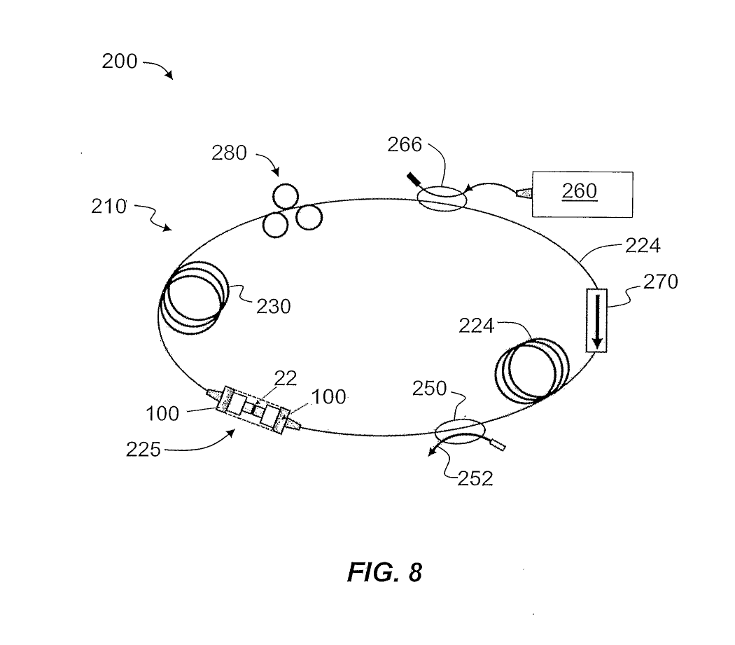

FIG. 7 is perspective view of optical fiber 10 having a graphene-based saturable absorber material 18 in the form of a hybrid film 60 assembled on fiber end facet 14, wherein the hybrid film is formed from an intercalation of a graphene film 62 and another material 64, such as an organic material. The saturable absorber device 22 of FIG. 7 is suitable for use in mode locking and Q-switching fiber lasers, as described below. In one example, the organic materials are conjugated molecules that can have photochromic properties.

In an example, the intercalation of the different layers of hybrid film 60 is adjusted to optimize the desired properties of the hybrid film In an example, the above mentioned technologies, such as layer-by-layer, transfer print or optical trapping, are combined to assemble the hybrid film on the fiber end facet.

### EXAMPLE 6

In Example 6, saturable absorber material 18 is provided on the fiber end facet 14, wherein the material is comprised of functionalized or derivatized graphene, wherein the graphene is derivatized by organic, inorganic or organometallic material to form a composite or a hybrid film with enhanced performance for mode locking, Q switching or optical limiting.

### EXAMPLE 7

With reference again to FIG. 7, in an example 7 saturable absorber material 18 comprising a hybrid film 60 is formed from a graphene-based polymer composite made from graphene or its derivatives (e.g., graphene, graphene oxide or functionalized graphene) 62 embedded in host polymers 64 to be used as saturable absorber. The choice of matrix polymers depends on properties such as transparency in the wavelength range of interest, reduction of propagation losses, a low refractive-index mismatch with the graphene materials, and good thermal and environmental stability. A non-exhaustive list of matrix polymers that can be used includes polyvinyl alcohol (PVA), polycarbonate (PC), polyimide and poly(phenylene vinylene) (PPV) derivatives, cellulose derivatives, conjugated polymers such as poly(3-hexylthiophene-2,5-diyl) (P3HT), poly(3,3″-dialkylquarterthiophene) (PQT).

Graphene materials and polymer hosts can be dispersed using, for example, ultrasonication or high-shear mixing in organic solvents such as dichlorobenzene (DCB) and hexane. Example methods for final deposition of thin films include spin coating, spray painting, drop casting, dip coating, vacuum filtration and printing, but are not limited to these aforementioned methods.

### Fiber Laser With Ring Cavity and Graphene-Based Saturable Absorber Device

FIG. 8 is a schematic diagram of a fiber laser 200 having a ring cavity 210 designed for mode locking and Q-switching by using graphene-based saturable absorber device 22. To obtain unambiguous evidence of soliton mode locking, i.e., clear solitonic sibebands, extra single-mode fiber (SMF) 224 is added to compensate for the normal dispersion of graphene so that the net cavity dispersion becomes anomalous. The two interfaced fiber pigtails 100 in ring cavity 210 constitute a “graphene mode locker” 225 that includes graphene-based saturable absorber device 22.

In this example, the fiber laser 200 has a ring cavity 210 having a section of 6.4 m erbium-doped fiber (EDF) 230 with group velocity dispersion (GVD) of 10 ps/km/nm, 8.3 m (6.4 m) and a SMF 224 with GVD 18 ps/km/nm. Solitonic sidebands are observed after an extra 100 m of SMF 224 is added in the cavity, demonstrating that the net cavity dispersion is anomalous in the present cavity. The total fiber dispersion is about 1.96 ps/nm. A 10% fiber coupler 250 is used to output the signal (as indicated by arrow 252).

Fiber laser 200 is pumped by a high power fiber Raman laser source 260 (BWC-FL-1480-1) of wavelength 1480 nm, which is coupled into laser cavity 210 using a wavelength-division multiplexer (WDM) 266. A polarization-independent isolator 270 is spliced into laser cavity 210 to force the unidirectional operation. An intra-cavity polarization controller 280 is used to change the cavity linear birefringence.

### Fiber Laser With Linear Cavity and Graphene-Based Saturable Absorber Device

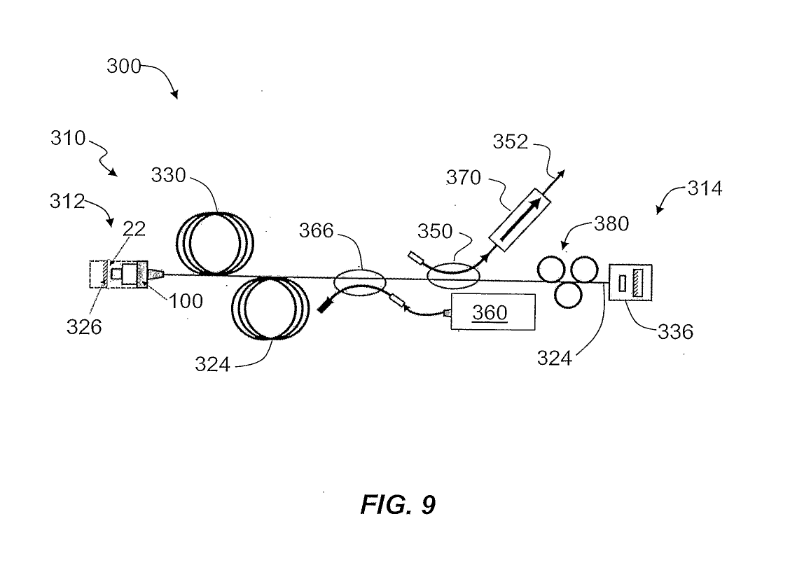

FIG. 9 is a schematic diagram of a fiber laser 300 having a linear cavity 310 designed for mode locking and Q-switching by using graphene-based saturable absorber device 22. The saturable absorber material 18 for graphene-based saturable absorber device 22 (see e.g., FIG. 1) includes, for example, graphene of different thicknesses, assembly structures or compositions, is coated as a film onto an optical element in the form of highly reflective mirror 326, which enables saturable absorber device 22 to operate in a reflective mode.

Mirror 326, together with graphene film 30 (see e.g., FIG. 3), is adhered to the fiber end facet 14 of fiber 10 supported in pigtail 100, which is placed at one end 312 of linear cavity 310. Linear cavity 310 includes SMF 324 and EDF 330. At the opposite side 314 of linear cavity 310, a Faraday mirror 336 is spliced to SMF 324. A fiber coupler 350 is used to output the signal through an isolator 370, with the outputted signal denoted by 352.

Fiber laser 300 is pumped by a high power fiber Raman laser source 360 (BWC-FL-1480-1) of wavelength 1480 nm, which is coupled to linear cavity 310 via a WDM 366. An intra-cavity polarization controller 380 is used to change the cavity linear birefringence. Bi-directional oscillation can be achieved in laser cavity 310.

### ADDITIONAL ASPECTS AND EXAMPLES OF THE INVENTION

According to a first aspect of the invention there is provided a saturable absorber material comprising graphene or a graphene derivative. Saturable absorption is a property of materials where the absorption of light decreases with increasing light intensity. Saturable absorbers are useful in laser cavities. The key parameters for a saturable absorber are its wavelength range (where it absorbs), its dynamic response (how fast it recovers), and its saturation intensity and fluence (at what intensity or pulse energy it saturates). They are commonly used for passive Q-switching or mode locking of lasers.

In a first embodiment of the first aspect of the invention, the saturable absorber material comprises graphene or its derivatives. Preferably said derivatives include, but are not limited to graphene oxide or graphene-polymer composites, hybrids of graphene and inorganic or organic materials.

In a second embodiment of the first aspect of the invention, the saturable absorber material comprises a multilayer (defined as two or more layers) graphene film.

In a third embodiment of the first aspect of the invention, the saturable absorber material comprises one or more monolayer graphene flakes with a small size (defined as less than 10 μm).

In a fourth embodiment of the first aspect of the invention, the saturable absorber material comprises composites of graphene and organic molecules. Preferably the composites of graphene and organic molecules exhibit photochromic properties.

In a fifth embodiment of the first aspect of the invention, the saturable absorber material comprises functionalized or derivatized graphene. The meaning of functionalization or derivatization of graphene in this context refers to the chemical attachment of chemical functional groups or dye molecules on the graphene or graphene oxide for the purpose of modifying its solubility, dispersability, electronic and optical properties. Preferably the functionalized or derivatized graphene is functionalized or derivatized from, but not limited to, organic, inorganic or organometallic materials.

In a sixth embodiment of the first aspect of the invention, the saturable absorber material comprises thin films (defined as 1 to 30 layers) of graphene-based polymer composite made from graphene or its derivatives embedded in host polymers. Preferably the graphene derivatives can be, but are not limited to, graphene, graphene oxide or functionalized graphene. Preferably the host polymer can be, but is not limited to, polyvinyl alcohol (PVA), polycarbonate (PC), polyimide and poly(phenylene vinylene) (PPV) derivatives, cellulose derivatives, and conjugated polymers such as poly(3-hexylthiophene-2,5-diyl) (P3HT), poly(3,3″-dialkylquarterthiophene) (PQT).

According to a second aspect of the invention, there is provided an optical fiber assembly comprising a graphene- or graphene derivative-based saturable absorber material assembled or deposited on an optical fiber. The optical fiber assembly comprises an example embodiment of a graphene-based saturable absorber device

In a first embodiment of the second aspect of the invention, the optical fiber assembly comprises a layer of graphene or its derivatives assembled on the end facet of an optical fiber. Preferably the graphene derivatives include, but are not limited to, graphene oxide or derivatized graphene, assembled on the end facet of an optical fiber.

In a second embodiment of the second aspect of the invention, the optical fiber assembly comprises a multilayer (defined as 1 to 30 layers of) graphene film deposited on the end facet of the optical fiber.

In a third embodiment of the second aspect of the invention, the optical fiber assembly comprises monolayer graphene flakes with a small size (defined as less than 10 μm) deposited onto the fiber end facet of the optical fiber.

In a fourth embodiment of the second aspect of the invention, the optical fiber assembly comprises composite films of graphene and organic molecules constructed on the end facet of the optical fiber. Preferably the composites of graphene and organic molecules exhibit photochromic properties.

In a fifth embodiment of the second aspect of the invention, the optical fiber assembly comprises functionalized or derivatized graphene films constructed on the end facet of the optical fiber.

Preferably the functionalized or derivatized graphene is functionalized or derivative from, but not limited to, organic, inorganic or organometallic materials.

In a sixth embodiment of the second aspect of the invention, the optical fiber assembly comprises of a film made from composites of graphene or graphene derivatives and polymer, transferred to the optical fiber end facet.

Preferably the graphene derivatives can be, but are not limited to, graphane, graphene oxide or functionalized graphene.

Preferably the host polymer can be, but is not limited to, polyvinyl alcohol (PVA), polycarbonate (PC), polyimide and poly(phenylene vinylene) (PPV) derivatives, cellulose derivatives, and conjugated polymers such as poly(3-hexylthiophene-2,5-diyl) (P3HT), poly(3,3″-dialkylquarterthiophene) (PQT).

According to a third aspect of the invention there is provided a method for preparing an optical fiber assembly comprising a graphene- or graphene derivative-based saturable absorber material, which comprises: a) preparing a graphene- or graphene derivative-based saturable absorber material, and b) transferring the graphene- or graphene derivative-based saturable absorber material to the end facet of an optical fiber.

In a first embodiment of the third aspect of the invention, the method for preparing a graphene-based saturable absorber material, consists of one of the following: mechanical exfoliation, epitaxial growth, chemical vapour deposition, chemical processing (solution processed) methods, laser ablation and filtered cathodic arc methods.

In a second embodiment of the third aspect of the invention, the method for transferring a prepared graphene- or graphene derivative-based saturable absorber material to the end facet of an optical fiber is using a polydimethylsiloxane (PDMS) stamp to transfer a printed graphene film onto the fiber end facet, which is suitable for a wide ranges of initial substrates where graphene or its derivatives is prepared.

In a third embodiment of the third aspect of the invention, the method for transferring a prepared graphene- or graphene derivative-based saturable absorber material to the end facet of an optical fiber, in which the saturable absorber material is a graphene film prepared by epitaxial growth and chemical vapour deposition, is via detachment from the original substrate by a floating-off process which involves etching the substrate in acid or salt solution.

In a fourth embodiment of the third aspect of the invention, the method for transferring a prepared graphene- or graphene derivative-based saturable absorber material to the end facet of an optical fiber, in which the saturable absorber material is mechanically exfoliated graphene, is by attaching adhesive tape containing a surface layer of graphene directly onto the fiber end facet by aligning the mechanically exfoliated graphene with the fiber pinhole.

In a fifth embodiment of the third aspect of the invention, the method for transferring a prepared graphene- or graphene derivative-based saturable absorber material to the end facet of an optical fiber is via the use of assembly technologies such as layer-by-layer, which is suitable for solution processed graphene of graphene dispersed in solvents.

In a sixth embodiment of the third aspect of the invention, the method for transferring a prepared graphene- or graphene derivative-based saturable absorber material to the end facet of an optical fiber is via the use of optical trapping, in which the clean optical fiber with tunable optical parameters is dipped into graphene solution.

In a seventh embodiment of the third aspect of the invention, the method for transferring a prepared graphene- or graphene derivative-based saturable absorber material to the end facet of an optical fiber is via the use of spin coating technique to form a polymer-graphene composite which is then applied on the fiber end facet.

In an eighth embodiment of the third aspect of the invention, the method for transferring a prepared graphene- or graphene derivative-based saturable absorber material to the end facet of an optical fiber is via the use of a graphene-ionic liquid gel to apply on the fiber end facet.

According to a fourth aspect of the invention there is provided a fiber laser, which contains graphene or graphene derivative-based saturable absorber materials. In this context, a fiber laser is a laser in which the active gain medium is an optical fiber doped with rare-earth elements such as erbium, ytterbium, neodymium, dysprosium, praseodymium, and thulium.

In a first embodiment of the fourth aspect of the invention, the fiber laser comprises a ring cavity which contains graphene or graphene derivative-based saturable absorber materials.

In a second embodiment of the fourth aspect of the invention, the fiber laser comprises a linear cavity which contains graphene or graphene derivative-based saturable absorber materials.

According to a fifth aspect of the invention there is provided the use of graphene or graphene derivative-based materials as saturable absorber in fiber lasers for the mode-locking, Q-switching, optical pulse shaping, optical switching, processing of optical signal of lasers.

1. A saturable absorber device for use in a laser cavity, comprising:
an optical element; and
a saturable absorber material operably supported by the optical element and comprising at least one of graphene, a graphene derivative and functionalized graphene.

2. A saturable absorber device according to claim 1, wherein the saturable absorber material comprises at least one of: at least one layer of graphene; at least one layer of graphene oxide; at least one layer of a graphene-polymer composite; at least one hybrid layer formed from graphene and at least one type of an inorganic material; at least one hybrid layer formed from graphene and at least one type of an organic material; at least one layer of graphene flakes; at least one layer of a thin film made from graphene or a graphene derivative embedded in a host polymer; graphane; and graphane oxide.

3. A saturable absorber device according to claim 1, wherein the saturable absorber material comprises a combination of graphene and photochromic organic molecules.

4. A saturable absorber device according to claim 1, wherein the saturable absorber material is functionalized or derivatized from at least one of an organic material, an inorganic material and an organometallic material.

5. A saturable absorber device according to claim 2, wherein the host copolymer is at least one of: polyvinyl alcohol (PVA), polycarbonate (PC), polyimide and poly(phenylene vinylene) (PPV) derivatives, cellulose derivatives, or conjugated polymers such as poly(3-hexylthiophene-2,5-diyl) (P3HT), poly(3,3″-dialkylquarterthiophene) (PQT).

6. A saturable absorber device according to claim 1, wherein the optical element includes an end facet, and wherein the saturable absorber material is supported by the optical element on the end facet.

7. A saturable absorber device according to claim 6, wherein the optical element comprises an optical fiber.

8. A saturable absorber device according to claim 7, further comprising a fiber holder that holds the optical fiber.

9. A saturable absorber device according to claim 8, wherein the fiber holder and optical fiber comprise a fiber pigtail.

10. A fiber laser, comprising:
a ring or linear laser cavity; and
a saturable absorber device operably arranged within the laser cavity, the saturable absorber device comprising: an optical element, and a saturable absorber material supported by the optical element, the saturable absorber material comprising at least one of graphene, a graphene derivative and functionalized graphene.

11. The fiber laser of claim 10, wherein the saturable absorber device is configured in the laser cavity so as to provide at least one of: mode-locking, Q-switching, optical pulse shaping, optical switching and optical signal processing.

12. The fiber laser of claim 10, wherein the optical element comprises an optical fiber.

13. The fiber laser of claim 11, wherein the optical fiber is held within an optical fiber pigtail.

14. A method of forming a saturable absorber device for use in a laser cavity, comprising:
providing an optical element; and
supporting with the optical element a saturable absorber material that includes at least one of graphene, a graphene derivative and functionalized graphene.

15. The method according to claim 14, further comprising preparing the saturable absorber material using at least one of: mechanical exfoliation, epitaxial growth, chemical vapour deposition, chemical processing, laser ablation, and a filtered cathodic arc method.

16. The method according to claim 14, wherein the optical element has an end facet, and further comprising applying the saturable absorber material to the end facet.

17. The method according to claim 16, wherein said applying includes using a polydimethylsiloxane (PDMS) stamp to transfer a printed graphene film onto the end facet.

18. The method according to claim 16, wherein said applying includes at least one of:
a) a floating-off process;
b) adhesive taping;
c) a layer-by-layer application;
d) optical trapping;
e) spin-coating;
f) a graphene-ionic liquid gel application; and
g) stamping.

19. The method according to claim 16, including providing the optical element as an optical fiber held in a fiber pigtail.

20. The method according to claim 14, including forming the saturable absorber material as at least one of: at least one layer of graphene; at least one layer of graphene oxide; at least one layer of a graphene-polymer composite; at least one hybrid layer formed from graphene and at least one type of an inorganic material; at least one hybrid layer formed from graphene and at least one type of an organic material; at least one layer of graphene flakes; at least one layer of a thin film made from graphene or a graphene derivative embedded in a host polymer; graphane; and graphane oxide.
